(19) United States
(12) Patent Application Publication
(10) Pub. No.: US 2024/0032404 A1
(43) Pub. Date: Jan. 25, 2024

(54) DISPLAY DEVICE AND METHOD OF FABRICATING THE SAME

(71) Applicant: Samsung Display Co., LTD., Yongin-si (KR)

(72) Inventors: Woong Sik KIM, Yongin-si (KR); Jin Su BYUN, Yongin-si (KR); Si Kwang KIM, Yongin-si (KR); Dong Hwan BAE, Yongin-si (KR)

(73) Assignee: Samsung Display Co., LTD., Yongin-si (KR)

(21) Appl. No.: 18/314,869

(22) Filed: May 10, 2023

(30) Foreign Application Priority Data
Jul. 22, 2022 (KR) 10-2022-0090917

(51) Int. Cl. H10K 59/80; H10K 59/122; H10K 59/12

(52) U.S. Cl. CPC H10K 59/879; H10K 59/122; H10K 59/1201

(57) ABSTRACT

A display device includes a substrate, an emission material layer disposed on the substrate and including a pixel having a pixel electrode, an emissive layer and a common electrode, and a pixel-defining film defining the pixel, a thin-film encapsulation layer disposed on the emission material layer, a low-refractive pattern layer overlapping the pixel-defining film and disposed on the thin-film encapsulation layer, an etch stop layer disposed on the low-refractive pattern layer and formed of an inorganic material, and a high-refractive planarization layer formed on the etch stop layer, wherein the high-refractive planarization layer includes a recess aligned with the low-refractive pattern layer.

### CROSS REFERENCE TO RELATED APPLICATION(S)

This application claims priority to and benefits of Korean Patent Application 10-2022-0090917 under 35 U.S.C. § 119, filed on Jul. 22, 2022, in the Korean Intellectual Property Office, the entire contents of which are incorporated herein by reference.

### BACKGROUND

### 1. Technical Field

Embodiments relate to a display device and a method for fabricating the display device.

### 2. Description of the Related Art

Display devices become more important as multimedia technology evolves. Accordingly, a variety of types of display devices such as liquid-crystal display (LCD) devices and organic light-emitting display (OLED) devices are currently used.

Among the display devices, an organic light-emitting display device displays images by using an organic light-emitting device that emits light by recombination of electrons and holes. Such a display device has advantages of fast response speed, high luminance, large viewing angle, and low power consumption.

A head-mounted display device may be mounted on a user's head and may have the form of a pair of glasses or a helmet. Such a head-mounted display device displays an image in front of the user's eyes so that the user can recognize the image.

### SUMMARY

Embodiments provide a display device capable of improving visibility.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device may include a substrate, an emission material layer disposed on the substrate and including a pixel including a pixel electrode, an emissive layer, and a common electrode; and a pixel-defining film defining the pixel, a thin-film encapsulation layer disposed on the emission material layer, a low-refractive pattern layer overlapping the pixel-defining film and disposed on the thin-film encapsulation layer, an etch stop layer disposed on the low-refractive pattern layer and formed of an inorganic material, and a high-refractive planarization layer formed on the etch stop layer, wherein the high-refractive planarization layer may include a recess overlapping the low-refractive pattern layer.

The recess of the high-refractive planarization layer may be aligned with the low-refractive pattern layer, and a width of the recess may gradually decrease as being closer to the low-refractive pattern layer from an upper surface of the high-refractive planarization layer.

The recess may have a depth greater than a thickness of the low-refractive pattern layer.

The recess may have an opening exposing the etch stop layer.

The recess may surround the emissive layer in a plan view.

The low-refractive pattern layer may surround the emissive layer in a plan view.

The high-refractive planarization layer may have a refractive index greater than a refractive index of the low-refractive pattern layer by about 0.05 to about 0.3.

The etch stop layer may have a refractive index that is smaller than the refractive index of the high-refractive planarization layer and greater than the refractive index of the low-refractive pattern layer.

The substrate may include a display area overlapping the emissive layer and a non-display area around the display area, and wherein the etch stop layer may entirely cover the display area and the non-display area.

The substrate may further include a metal pad disposed in the non-display area, and wherein the etch stop layer may include an opening exposing the metal pad.

In an embodiment, a display device may include a substrate; an emission material layer disposed on the substrate and including a pixel including a pixel electrode, an emissive layer, and a common electrode; and a pixel-defining film defining the pixel, a thin-film encapsulation layer disposed on the emission material layer, an etch stop layer disposed on the thin-film encapsulation layer and formed of an inorganic material and a high-refractive planarization layer formed on the etch stop layer, wherein the high-refractive planarization layer may have a recess overlapping the pixel-defining film.

The recess of the high-refractive planarization layer may be aligned with the pixel-defining film, and a width of the recess may decrease as being closer to the etch stop layer from an upper surface of the high-refractive planarization layer.

The recess may be filled with a filler having a refractive index smaller than the refractive index of the high-refractive planarization layer.

The substrate may include a display area overlapping the emissive layer and a non-display area around the display area, and wherein the etch stop layer may entirely cover the display area and the non-display area.

The substrate may further include a metal pad disposed in the non-display area, and wherein the etch stop layer may include an opening exposing the metal pad.

In an embodiment, a method of fabricating a display device may include forming a display panel by sequentially stacking a substrate, an emission material layer including a pixel-defining film and a pixel, and a thin-film encapsulation layer for protecting the emission material layer, forming a low-refractive pattern layer on the thin-film encapsulation layer overlapping the pixel-defining film, forming an etch stop layer entirely on the display panel to cover the low-refractive pattern layer, forming a high-refractive planarization material on the etch stop layer, etching the high-refractive planarization material to form a recess overlapping the low-refractive pattern layer and forming a high-refractive planarization layer by curing the high-refractive planarization material.

The low-refractive pattern layer is aligned with the pixel-defining film, the recess of the high-refractive planarization layer may be aligned with the low-refractive pattern layer, and the forming of the etch stop layer may include forming the etch stop layer entirely in a display area and a non-display area of the display panel.

The method may further include: forming an opening exposing a metal pad disposed in the non-display area by etching the etch stop layer.

The forming of the low-refractive pattern layer may be performed by a photo-lithography process, and wherein the forming of the high-refractive planarization material may be performed by an ink-jet process.

The recess may be formed by etching by using a hard mask.

According to embodiments, the emission area of a display device may be increased, and the emission efficiency may be improved.

However, the effects of the disclosure are not limited to the aforementioned effects, and various other effects are included in the description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view showing a display device according to an embodiment.

FIG. 2 is a schematic cross-sectional view of the display device, taken along line Xa-Xa′ of FIG. 1.

FIG. 3 is a schematic plan view showing a single pixel of a display device according to an embodiment.

FIG. 4 is a schematic enlarged view of area A of FIG. 3.

FIG. 5 is a schematic plan view of a display device according to an embodiment.

FIG. 6 is a schematic plan view showing a pixel of a display device according to an embodiment.

FIG. 7 is a schematic enlarged view of area B of FIG. 6.

FIG. 8 is a schematic cross-sectional view taken along line I-I′ of FIG. 1.

FIG. 9 is a schematic plan view showing a pixel of a display device according to an embodiment.

FIGS. 10 to 18 are schematic cross-sectional views showing a part of a display device for illustrating a method of fabricating the display device according to an embodiment.

FIGS. 19 to 25 are schematic views for illustrating a method of fabricating a display device according to an embodiment.

FIG. 26 is a schematic view showing a configuration of a head-mounted display device according to an embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the description and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the description and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the description.

Hereinafter, embodiments will be described in detail with reference to the accompanying drawings.

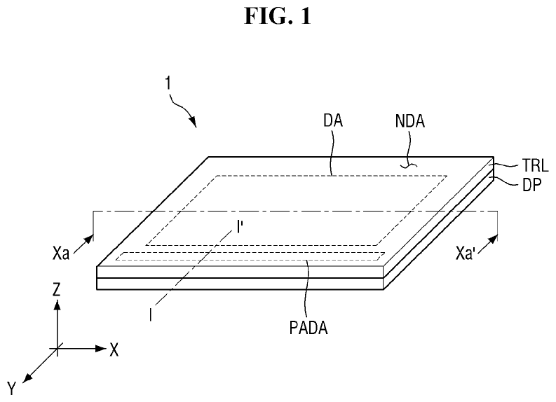

FIG. 1 is a schematic perspective view showing a display device according to an embodiment.

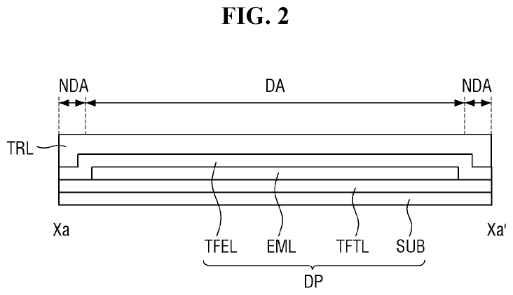

FIG. 2 is a schematic cross-sectional view of the display device, taken along line Xa-Xa′ of FIG. 1.

Referring to FIGS. 1 and 2, the display device 1 may include a display panel DP and a total reflection layer TRL.

The display panel DP may be either a rigid display panel or a flexible display panel. For a flexible display panel, the display panel DP may be deformable in shape by bending, folding, rolling, or the like. For example, the display panel DP may be a display panel including organic light-emitting elements.

The display panel DP may include a display area DA and a non-display area NDA. In the display area DA, images may be displayed. In the non-display area NDA adjacent to the display area DA, image may not be displayed. The non-display area NDA may surround the display area DA. However, embodiments are not limited thereto. For example, the non-display area NDA may be adjacent to only a part of the edge portion of the display area DA.

For example, the display device 1 may include a pad area PADA. Pad units may be disposed in the pad area PADA. The pad units may be disposed on the upper side of the display panel DP. The pad units may include pads connected to external circuit boards.

The display panel DP may include a substrate SUB, and a thin-film transistor layer TFTL, an emission material layer EML and a thin-film encapsulation layer TFEL disposed on the substrate SUB.

The substrate SUB may be made of an insulating material such as glass, quartz and a polymer resin. For example, the the polymer resin may include polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP) or a combination thereof. In another example, the substrate SUB may include a metallic material.

The substrate SUB may be a rigid substrate or a flexible substrate that is bendable, foldable, rollable, and so on. In case that the substrate SUB is a flexible substrate, the substrate SUB may be formed of polyimide (PI). However, embodiments are not limited thereto.

The thin-film transistor layer TFTL may be disposed on the substrate SUB. On the thin-film transistor layer TFTL, scan lines, data lines, power supply lines, scan control lines, routing lines connecting the pads with the data lines may be formed as well as thin-film transistors in the pixels. Each of the thin-film transistors may include a gate electrode, a semiconductor layer, a source electrode and a drain electrode.

The thin-film transistor layer TFTL may be disposed in the display area DA and the non-display area NDA. For example, the thin-film transistors in the pixels, the scan lines, the data lines, and the power supply lines on the thin-film transistor layer TFTL may be disposed in the display area DA. The scan control lines and the link lines on the thin-film transistor layer TFTL may be disposed in the non-display area NDA.

The emission material layer EML may be disposed on the thin-film transistor layer TFTL. The emission material layer EML may be an organic emissive layer, a quantum-dot emissive layer, a nano LED layer, or a micro LED layer. The organic emissive layer may include an organic light-emitting material. The quantum-dot emissive layer may include quantum dots and quantum rods. The nano LED layer and the micro LED layer may include small LED devices of several hundred micrometers or less. In the following description, an organic emissive layer will be described as the emission material layer EML.

According to an embodiment, the emission material layer EML may include pixels including a first electrode, an emissive layer and a second electrode, and a pixel-defining layer. The emissive layer may be an organic emissive layer containing an organic material. For example, the emissive layer may include a hole transporting layer, an organic light-emitting layer and an electron transporting layer. In case that a voltage is applied to the first electrode and a cathode voltage is applied to the second electrode through the thin-film transistor on the thin-film transistor layer TFTL, the holes and electrons may move to the organic light-emitting layer through the hole transporting layer and the electron transporting layer, respectively, such that the holes and electrons may combine in the organic light-emitting layer to emit light. The pixels on the emission material layer EML may be disposed in the display area DA.

A thin-film encapsulation layer TFEL may be disposed on the emission material layer EML. The thin-film encapsulation layer TFEL may function to prevent oxygen or moisture from permeating into the emission material layer EML. For example, the thin-film encapsulation layer TFEL may include at least one inorganic layer. The inorganic layer may be a silicon nitride layer, a silicon oxynitride layer, a silicon oxide layer, a titanium oxide layer, or an aluminum oxide layer. However, embodiments are not limited thereto. For example, the thin-film encapsulation layer TFEL may protect the emission material layer EML from foreign substances such as dust. For example, the thin-film encapsulation layer TFEL may include at least one organic layer. The organic layer may be formed of an acryl resin, an epoxy resin, a phenolic resin, a polyamide resin and a polyimide resin. However, embodiments are not limited thereto.

The thin-film encapsulation layer TFEL may be disposed in the display area DA as well as the non-display area NDA. For example, the thin-film encapsulation layer TFEL may cover the display area DA and the emission material layer EML and may cover the thin-film transistor layer TFTL in the non-display area NDA.

The total reflection layer TRL may be disposed on the display panel DP. The total reflection layer TRL may include at least one of a light path control layer that changes a light path, and an anti-reflection layer that reduces reflectance of external light incident from the outside.

For example, an optically transparent window may be disposed on the total reflection layer TRL. Accordingly, the image generated by the display panel DP may pass through the window. The window may be attached to the total reflection layer TRL by a transparent adhesive member such as an optically clear adhesive (OCA) film.

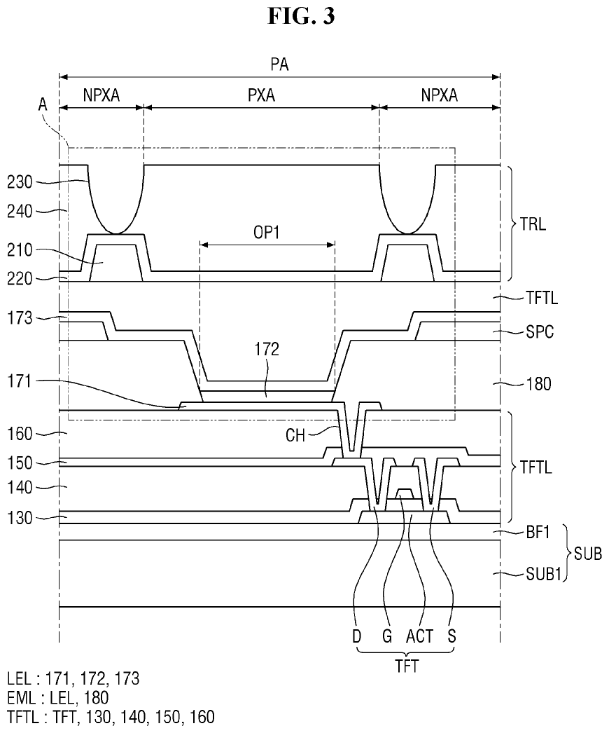

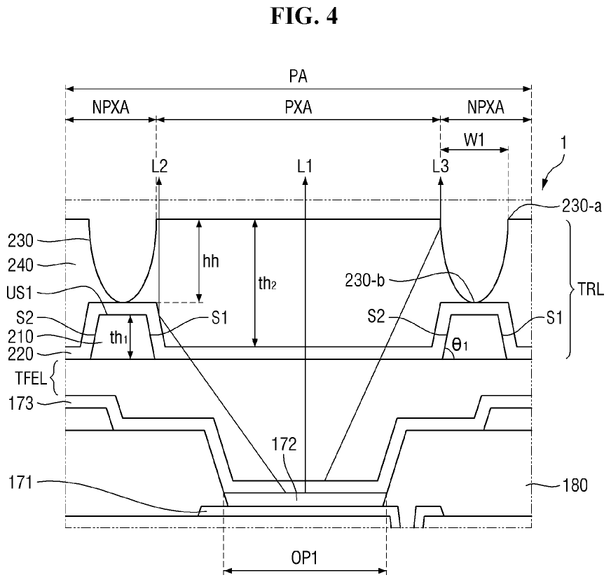

FIG. 3 is a schematic plan view showing a single pixel of a display device according to an embodiment. FIG. 4 is a schematic enlarged view of area A of FIG. 3.

Referring to FIGS. 3 and 4, the thin-film transistor layer TFTL may be formed on the substrate SUB. The thin-film transistor layer TFTL may include thin-film transistors TFT, a gate insulator 130, an interlayer dielectric film 140, a protective film 150, and a planarization film 160.

A buffer film BF1 may be formed on a surface of the substrate SUB1. The buffer film BF1 may be formed on a surface of the substrate SUB1 in order to protect the thin-film transistors TFT and an emissive layer 172 of the emission material layer EML from permeating through the substrate SUB1. The buffer film BF1 may be formed of inorganic films stacked on one another alternately. For example, the buffer film BF1 may be made up of multiple layers in which one or more inorganic layers of a silicon nitride layer, a silicon oxynitride layer, a silicon oxide layer, a titanium oxide layer and an aluminum oxide layer are alternately stacked on one another. In another example, the buffer film BF1 may be omitted.

A thin-film transistor TFT may be formed on the buffer film BF1. The thin-film transistor TFT may include an active layer ACT, a gate electrode G, a source electrode S, and a drain electrode D. In FIG. 3, the thin-film transistor TFT may be implemented as a top-gate transistor in which the gate electrode G is positioned above the active layer ACT. However, embodiments are not limited thereto. For example, each of the thin-film transistors TFT may be implemented as a bottom-gate transistor in which the gate electrode G is positioned below the active layer ACT, or as a double-gate transistor in which the gate electrodes G are disposed above and below the active layer ACT.

The active layer ACT may be formed on the buffer film BF1. The active layer ACT may include polycrystalline silicon, single crystal silicon, low-temperature polycrystalline silicon, amorphous silicon, or an oxide semiconductor. The oxide semiconductor may include, for example, a binary compound (ABₓ), a ternary compound (ABₓC_{y}) and a quaternary compound (ABₓC_{y}D_{z}) containing indium, zinc, gallium, tin, titanium, aluminum, hafnium (Hf), zirconium (Zr), magnesium (Mg), etc. For example, the active layer ACT may include an oxide including indium, tin, and titanium (ITZO) or an oxide including indium, gallium and tin (IGZO). A light-blocking layer for blocking light incident on the active layer ACT from the outside may be formed between the buffer film and the active layer ACT.

The gate insulator 130 may be formed on the active layer ACT. The gate insulator 130 may be formed of an inorganic layer, for example, a silicon nitride layer, a silicon oxynitride layer, a silicon oxide layer, a titanium oxide layer, or an aluminum oxide layer.

The gate electrode G and a gate line may be formed on the gate insulator 130. The gate electrodes G and the gate lines may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The interlayer dielectric film 140 may be formed over the gate electrode G and the gate line. The interlayer dielectric film 140 may be formed of an inorganic layer, for example, a silicon nitride layer, a silicon oxynitride layer, a silicon oxide layer, a titanium oxide layer, or an aluminum oxide layer.

The source electrode S and the drain electrode D may be formed on the interlayer dielectric film 140. Each of the source electrodes S and the drain electrodes D may be connected to the active layer ACT through a contact hole penetrating through the gate insulator 130 and the interlayer dielectric film 140. The source electrode S and the drain electrode D may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The protective film 150 may be formed over the source electrode S and the drain electrode D in order to insulate the thin-film transistor TFT. The protective film 150 may be formed of an inorganic layer, for example, a silicon nitride layer, a silicon oxynitride layer, a silicon oxide layer, a titanium oxide layer, or an aluminum oxide layer.

The planarization film 160 may be formed on the protective film 150 to provide a flat surface over the step differences of the thin-film transistors TFT. The planarization film 160 may be formed of an organic layer such as an acryl resin, an epoxy resin, a phenolic resin, a polyamide resin and a polyimide resin.

An emission material layer EML may be disposed on the planarization film 160. The emission material layer EML (see FIG. 2) may include light-emitting elements LEL and a pixel-defining film 180. Each of the light-emitting elements LEL may include a pixel electrode 171, an emissive layer 172, and a common electrode 173. The common electrode 173 may be connected (e.g., commonly connected) to the light-emitting elements LEL.

The pixel electrode 171 may be formed on the planarization film 160. According to an embodiment, the pixel electrode 171 may be an anode electrode. In case that the pixel electrode 171 is an anode electrode, the pixel electrode 171 may include a reflective material. The reflective material may include, for example, a reflective layer made of at least one selected from the group consisting of silver (Ag), magnesium (Mg), chromium (Cr), gold (Au), platinum (Pt), nickel (Ni), copper (Cu), tungsten (W) and aluminum (Al), and a transparent or translucent electrode formed on the reflective layer.

The transparent or transflective electrode may be made of at least one selected from the group consisting of indium tin oxide (ITO), indium zinc oxide (IZO), zinc oxide (ZnO), In₂O₃ (Indium Oxide), indium gallium oxide (IGO), and aluminum zinc oxide (AZO).

A contact hole CH may be formed in the planarization film 160. The contact hole CH may be formed to expose the drain electrode D of the thin-film transistor TFT. The pixel electrode 171 may be connected to the drain electrode D of the thin-film transistor TFT through the contact hole CH.

The pixel-defining film 180 may distinguish between light-emitting elements LEL formed on the substrate SUB, and thus may define emission areas.

The pixel-defining film 180 may be formed on the planarization film 160. The pixel-defining film 180 may not be formed on the entire surface of the planarization film 160, but may include an opening OP1 to expose at least a part of the pixel electrode 171. The pixel-defining film 180 may be formed to cover the edge portion of the pixel electrode 171.

The pixel-defining film 180 may be formed between adjacent pixel electrodes 171 formed on the planarization film 160.

The pixel-defining film 180 may be formed of an organic layer such as an acryl resin, an epoxy resin, a phenolic resin, a polyamide resin and a polyimide resin.

The emissive layer 172 may be formed on the pixel-defining film 180. The emissive layer 172 may be disposed on a part of the pixel electrode 171 exposed through the opening OP1. According to an embodiment, the emissive layer 172 may cover at least a part of the opening OP1 of the pixel-defining film 180.

For example, the emissive layer 172 may emit one of red light, green light, and blue light. The wavelength of the red light may be in a range of about 620 to about 750 nm, and the wavelength of the green light may be in a range of about 495 to about 570 nm. Further, the wavelength of the blue light may be in a range of about 450 to about 495 nm.

According to an embodiment, the emissive layer 172 may emit white light. In case that the emission layer 172 emits white light, the emission layer 172 may have a stack structure of a red emission layer, a green emission layer and a blue emission layer. For example, additional color filters for displaying red, green and blue colors, respectively, may be further included in the emission layer 172.

For example, the emissive layer 172 may be made up of a multi-layer structure including a hole transporting layer, an organic light-emitting layer, an electron transporting layer, etc.

A spacer SPC may be further disposed between the pixel-defining film 180 and the common electrode 173. A surface of the spacer SPC may be in contact with the pixel-defining film 180, and the opposite surface of the spacer SPC may be in contact with the common electrode 173. The spacer SPC may maintain a gap between the pixel-defining film 180 and the common electrode 173. The spacer SPC may be made of an organic material, an inorganic material, or the like. For example, the spacer SPC may be formed of an organic material such as a photoresist, a polyacrylic resin, a polyimide resin, and an acrylic resin. In another example, the spacer SPC may be omitted.

The common electrode 173 may be disposed on the emissive layer 172 and the pixel-defining film 180. According to an embodiment, the common electrode 173 may be disposed (e.g., entirely disposed) on the emissive layer 172 and the pixel-defining film 180. The common electrode 173 may be a common layer formed across all of the light-emitting elements LEL. In an embodiment, the common electrode 173 may be a cathode electrode. In an embodiment, the common electrode 173 may include at least one selected from the group consisting of Li, Ca, LiF/Ca, LiF/Al, Al, Ag and Mg. For example, the common electrode 173 may be made of a metal thin film having a low work function. In an embodiment, the common electrode 173 may be made of at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO).

In the top-emission structure, the common electrode 173 may be formed of a transparent conductive oxide (TCO) such as indium tin oxide (ITO) and indium zinc oxide (IZO) that transmit light, or a semi-transmissive conductive material such as magnesium (Mg), silver (Ag) and an alloy of magnesium (Mg) and silver (Ag). In case that the common electrode 173 is formed of a semi-transmissive metal material, the light extraction efficiency may be increased by using microcavities.

The thin-film encapsulation layer TFEL may be disposed on the common electrode 173. The thin-film encapsulation layer TFEL may be disposed on the common electrode 173. The thin-film encapsulation layer TFEL may include at least one inorganic film to prevent oxygen or moisture from permeating into the emissive layer 172 and the common electrode 173. For example, the thin-film encapsulation layer TFEL may include at least one organic layer to protect the emission material layer EML from particles such as dust. For example, the thin-film encapsulation layer TFEL may include a first inorganic film disposed on the common electrode 173, an organic film disposed on the first inorganic film, and a second inorganic film disposed on the organic film. The first inorganic layer and the second inorganic layer may be formed of a silicon nitride layer, a silicon oxynitride layer, a silicon oxide layer, a titanium oxide layer, or an aluminum oxide layer. However, embodiments are not limited thereto. The organic layer may be formed of an acryl resin, an epoxy resin, a phenolic resin, a polyamide resin and a polyimide resin. However, embodiments are not limited thereto.

For example, a second buffer film may be formed on the thin-film encapsulation layer TFEL. The second buffer film may be made up of multiple inorganic films stacked on one another. For example, the second buffer film may be made up of multiple layers in which one or more inorganic layers of a silicon nitride layer, a silicon oxynitride layer, a silicon oxide layer, a titanium oxide layer and an aluminum oxide layer are alternately stacked on one another. In another example, the second buffer film may be omitted.

The total reflection layer TRL may be formed on the thin-film encapsulation layer TFEL.

The total reflection layer TRL may guide the paths of lights that are emitted from the emissive layer 172 and transmit in a direction intersecting a third direction (e.g., Z-axis direction) so that the lights may emit generally in the third direction (e.g., Z-axis direction). Accordingly, the total reflection layer TRL may collect lights.

The total reflection layer TRL may include a low-refractive pattern layer 210, an etch stop layer 220, a recess 230, and a high-refractive planarization layer 240.

The low-refractive pattern layer 210 may be disposed on the thin-film encapsulation layer TFEL. The low-refractive pattern layer 210 may overlap the pixel-defining film 180 but not with an emission area PXA. The low-refractive pattern layer 210 may be disposed to surround the emission area PXA in a plan view. The low-refractive pattern layer 210 may be formed by photo-lithography, and may be made of a polymer-based material. The polymer-based material may include one selected from the group consisting of acrylic resin, epoxy resin, polyimide, and polyethylene. However, embodiments are not limited thereto.

The low-refractive pattern layer 210 may be a layer that totally reflects the lights that are emitted from the emissive layer 172 and transmit toward side directions instead of the upward direction (e.g., Z-axis direction) so that the lights may transmit in the upward direction (e.g., Z-axis direction). The low-refractive pattern layer 210 will be described below with reference to FIG. 4.

The etch stop layer 220 may be disposed on the low-refractive pattern layer 210 to protect the underlying layers during an etching process for forming the recess 230 to be described below. The etch stop layer 220 may be made of, for example, an inorganic material such as a silicon nitride film.

The etch stop layer 220 may have a refractive index smaller than the refractive index of the high-refractive planarization layer 240 and greater than the refractive index of the low-refractive pattern layer 210.

The high-refractive planarization layer 240 may be disposed on the etch stop layer 220. For example, the high-refractive planarization layer 240 may provide a flat upper surface. The high-refractive planarization layer 240 may be formed by inkjet printing process, screen printing process, etc. The high-refractive planarization layer 240 may include at least one of zirconium oxide particles, aluminum oxide particles and titanium oxide particles and siloxane. However, embodiments are not limited thereto. The material of the high-refractive planarization layer 240 is not limited thereto.

The first refractive index of the high-refractive planarization layer 240 may be higher (or greater) than the second refractive index of the low-refractive pattern layer 210. The first refractive index of the high-refractive planarization layer 240 may be in a range of about 1.65 to about 1.75. For example, the first refractive index may be about 1.7. The second refractive index of the low-refractive pattern layer 210 may be in a range of about 1.45 to about 1.55. For example, the second refractive index may be about 1.53. A difference in refractive index between the high-refractive planarization layer 240 and the low-refractive pattern layer 210 may be a range of about 0.1 to about 0.25. Lights may be refracted or totally reflected due to a difference in refractive index between the side surface of the low-refractive pattern layer 210, the recess 230 and the high-refractive planarization layer 240. Accordingly, the light paths of the lights emitted from the emissive layer 172 may be changed into the third direction or a direction close to the third direction. As a result, the light efficiency of the display device 1 (see FIG. 1) may be improved.

The high-refractive planarization layer 240 may have the recess 230 in line with the low-refractive pattern layer 210. For example, the recess 230 may be aligned with the low-refractive pattern layer 210 and may extend along the the low-refractive pattern layer 210. The recess 230 may be formed in a U-shape. The recess 230 may have an opening that exposes the etch stop layer 220. The recess 230 may function to guide side lights toward the upper side similarly to the low-refractive pattern layer 210.

Referring to FIG. 4, the low-refractive pattern layer 210 may overlap a non-emission area NPXA of a pixel area PA. The low-refractive pattern layer 210 may be a layer that reflects (e.g., totally reflects) the lights that are emitted from the emissive layer 172 and transmit toward side directions instead of the upward direction (e.g., Z-axis direction) so that the lights may transmit in the upward direction (e.g., Z-axis direction). The low-refractive pattern layer 210 may overlap the pixel-defining film 180, but may not overlap the emission area PXA. The emission layer 172 may be included in the emission area PXA. For example, the low-refractive pattern layer 210 may not overlap the emissive layer 172.

The low-refractive pattern layer 210 may include an inclined surface having an inclination angle with respect to the surface of the thin-film encapsulation layer TFEL. The taper angle θ₁ of the inclined surface, e.g., the inclination angle may be a range of about 70 degrees to about 90 degrees. The taper angle θ₁ refers to the inclination angle of the inclined surface S2 of the low-refractive pattern layer 210, and indicates the angle formed between the thin-film encapsulation layer TFEL and the inclined surface S2 of the low-refractive pattern layer 210.

As the thickness th1 of the low-refractive pattern layer 210 increases, the ratio of the lights that are emitted from the emissive layer 172, are totally reflected by the inclined surfaces S1 and S2 of the low-refractive pattern layer 210 and transmit in the upward direction (e.g., Z-axis direction) may increase. Therefore, in order to increase the emission efficiency of lights from the pixel, the thickness th1 of the low-refractive pattern layer 210 may be in a range of about 1.5 μm to about 2.5 μm. As shown in FIG. 4, the thickness th1 of the low-refractive pattern layer 210 refers to the distance from the lower surface to the upper surface US1 of the low-refractive pattern layer 210.

The thickness th2 of the high-refractive planarization layer 240 refers to the distance from the lower surface to the upper surface of the high-refractive planarization layer 240, and may be in a range of about 3.5 μm to about 6 The recess 230 formed in the high-refractive planarization layer 240 may be formed in a U-shape, and may have a depth hh in a range of about 2.0 μm to about 3.5 μm.

The recess 230 may be formed in a wedge structure in which the width w1 of the opened end portion 230-a gradually decreases as being closer to the opposite end portion 230-b exposing the etch stop layer 220, and the inner surface connecting the opened end portion 230-a with the opposite end portion 230-b may be inclined. For example, the recess 230 may be formed in a U-shape, and the center portion of the opposite end portion 230-b may be rounded.

The low-refractive pattern layer 210 and the recess 230 of the total reflection layer TRL may guide lights that are emitted from the emission material layers EML and transmit in the side directions rather than the upward direction so that the lights may transmit toward the upper side of the emissive layer 172, thereby increasing the emission areas.

For example, the lights emitted from the emissive layer 172 may include a second light L2 and a third light L3 that transmit toward the low-refractive pattern layer 210 or the recess 230 of the total reflection layer TRL. For convenience of illustration, a light that is emitted from the emissive layer 172 and transmits toward the low-refractive pattern layer 210 or the recess 230 instead of the upper side may be referred to as a side light. In FIG. 4, the second light L2 and the third light L3 may be referred to as side lights.

A first light L1 may transmit upward from the emissive layer 172, may pass through the total reflection layer TRL, and may emit through the upper surface of the display device 1.

The second light L2 may transmit on a side surface of the emissive layer 172, may be reflected by the inclined surface S1 of the low-refractive pattern layer 210, and may pass through the high-refractive planarization layer 240 to emit.

The third light L3 may transmit on a side surface of the emissive layer 172, may be reflected by the recess 230, and may pass through the high-refractive planarization layer 240 to emit. For example, the recess 230 may be filled with air or a filler. The refractive index of the air or the filler with which the recess 230 is filled may have a lower refractive index than that of the high-refractive planarization layer 240. For example, the refractive index of the air or the filler with which the recess 230 is filled may be in a range of about 1 to about 1.55.

The refractive index difference between the low-refractive pattern layer 210 and the high-refractive planarization layer 240 may be in a range of about 0.05 to about 0.3. According to an embodiment, the inclination angle of the low-refractive pattern layer 210 may be about 70°, the refractive index of the low-refractive pattern layer 210 may be about 1.53, and the refractive index difference between the low-refractive pattern layer 210 and the lens LA may be about 0.14.

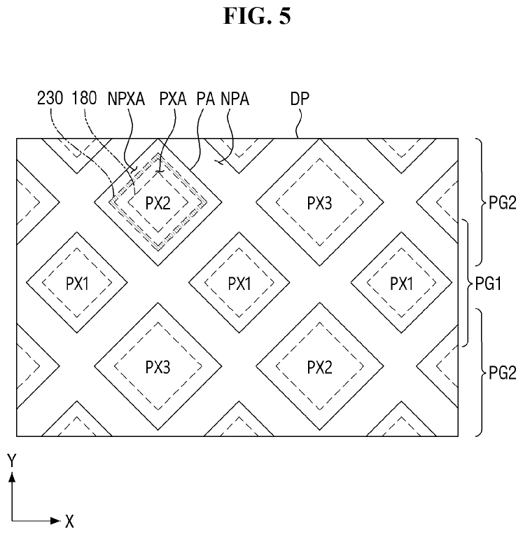

FIG. 5 is a schematic plan view of a display device according to an embodiment.

Referring to FIG. 5, the display device may include pixel groups. For example, the pixel groups may include first pixel groups PG1 and second pixel groups PG2. The first pixel groups PG1 and the second pixel groups PG2 may be arranged alternately along the first direction (e.g., Y-axis direction).

The first pixel groups PG1 may include first pixels PX1. The first pixels PX1 may be arranged along the second direction (e.g., X-axis direction). The second pixel groups PG2 may include second pixels PX2 and third pixels PX3. The second pixels PX2 and the third pixels PX3 may be arranged alternately in the second direction (e.g., X-axis direction). A non-pixel area NPA may be defined between the first, second, and third pixels PX1, PX2 and PX3.

The arrangement structure of the first, second, and third pixels PX1, PX2 and PX3 shown in FIG. 5 is merely illustrative, and embodiments are not limited thereto. For example, according to an embodiment, the first pixel PX1, the second pixel PX2 and the third pixel PX3 may be arranged sequentially and repeated in the second direction (e.g., X-axis direction) in a stripe shape. Although each of the first, second, and third pixels PX1, PX2 and PX3 may have a rectangular shape as an example, embodiments are not limited thereto. Each of the first, second, and third pixels PX1, PX2 and PX3 may have any of a variety of shape such as a polygonal shape, circular shape and an elliptical shape. As another example, the first, second, and third pixels PX1, PX2 and PX3 may have different shapes. For example, the first pixel PX1 may have a circular shape, and the second and third pixels PX2 and PX3 may have a rectangular shape.

Although the size of the first pixels PX1 is smaller than the size of the second pixels PX2 and the third pixels PX3 in the example shown in FIG. 5, embodiments are not limited thereto. For example, according to an embodiment, the first, second, and third pixels PX1, PX2 and PX3 may have the same size.

As an example, the first pixels PX1 may be green pixels, the second pixels PX2 may be blue pixels, and the third pixels PX3 may be red pixels. However, embodiments are not limited thereto.

In the plan view of FIG. 5, the non-emission area NPXA may be disposed to surround the emission area PXA. For example, the low-refractive pattern layer 210 (see FIG. 3) may be disposed in the non-emission area NPXA to surround the emission area PXA. For example, the recess 230 (see FIG. 3) may be positioned in the non-emission area NPXA to overlap the low-refractive pattern layer 210 (see FIG. 3) and may surround the emission area PXA.

For example, the high-refractive planarization layer 240 (see FIG. 3) may be formed on the entire surface of the non-pixel area NPA, the non-emission area NPXA, and the emission area PXA.

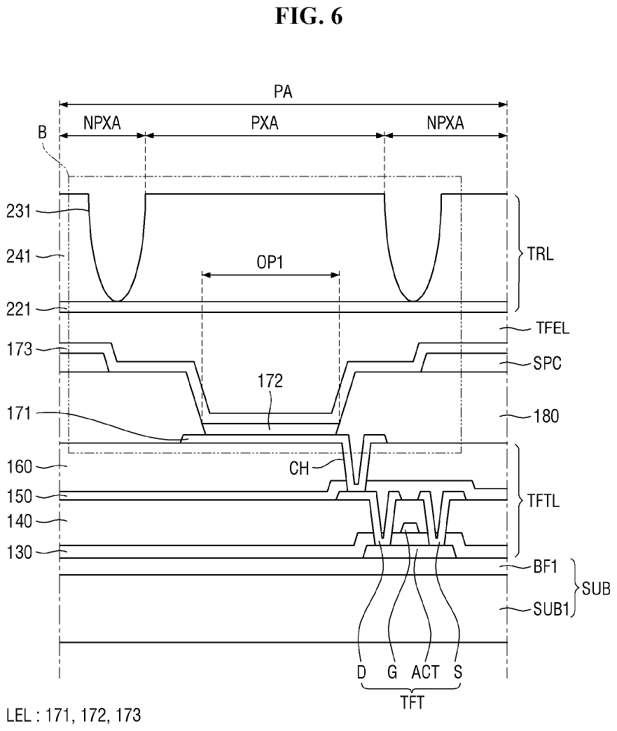

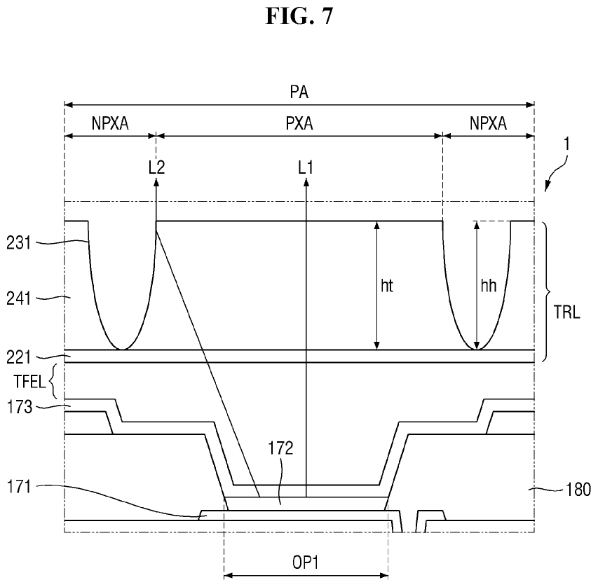

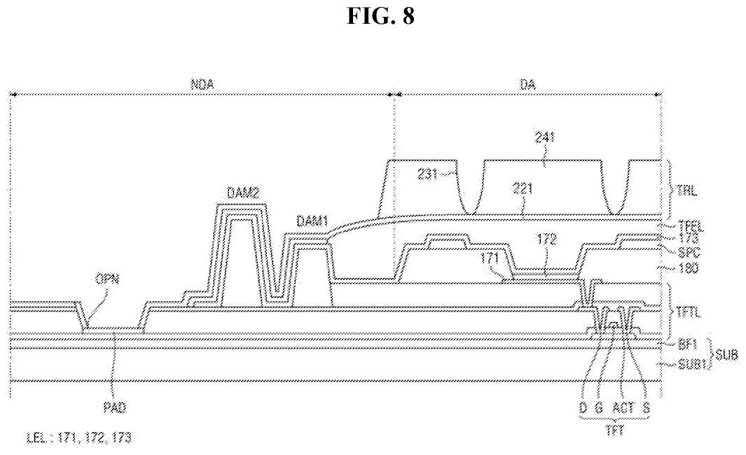

FIG. 6 is a schematic plan view showing a single pixel of a display device according to an embodiment. FIG. 7 is a schematic enlarged view of area B of FIG. 6. FIG. 8 is a schematic cross-sectional view taken along line I-I′ of FIG. 1.

The embodiment of FIGS. 6 and 7 is substantially identical to the embodiment of FIGS. 4 and 5 except that the low-refractive pattern layer 210 (see FIG. 4) is omitted and an etch stop layer 221 is disposed on an encapsulation layer TFEL; and, therefore, the redundant descriptions will be omitted for descriptive convenience.

A total reflection layer TRL may be formed on the thin-film encapsulation layer TFEL.

The total reflection layer TRL may guide the paths of lights that are emitted from the emissive layer 172 and transmit in a direction intersecting a third direction (e.g., Z-axis direction) so that the lights may emit generally in the third direction (e.g., Z-axis direction). Accordingly, the total reflection layer TRL may collect lights.

Referring to FIGS. 6 to 8, the total reflection layer TRL may include an etch stop layer 221, a recess 231 and a high-refractive planarization layer 241.

The etch stop layer 221 may be disposed on the thin-film encapsulation layer TFEL to protect the underlying layers during an etching process for forming a recess 231 to be described below. The etch stop layer 221 may be made of, for example, an inorganic material such as a silicon nitride film.

The etch stop layer 221 may have a refractive index smaller than that of the high-refractive planarization layer 241.

As shown in FIG. 8, the etch stop layer 221 may be disposed not only in the display area DA but also in the non-display area NDA.

The etch stop layer 221 may include an opening OPN exposing a metal pad PAD disposed in the non-display area NDA. Dam members DAM1 and DAM2 may be disposed between the display area DA and the metal pad PAD in the non-display area NDA in a plan view. The dam members DAM1 and DAM2 may prevent the material of the thin-film encapsulation layer TFEL from overflowing to the non-display area NDA.

The high-refractive planarization layer 241 may be disposed on the etch stop layer 221. For example, the high-refractive planarization layer 241 may provide a flat upper surface. The high-refractive planarization layer 241 may be formed by inkjet printing process, screen printing process, etc. The high-refractive planarization layer 241 may include at least one of zirconium oxide particles, aluminum oxide particles and titanium oxide particles and siloxane. However, embodiments are not limited thereto. The material of the high-refractive planarization layer 241 is not limited thereto.

The high-refractive planarization layer 241 may have the recess 231 in line with the pixel-defining film 180. For example, the recess 231 may extend along along end portions of the pixel-defining film 180. The recess 231 may be formed in a U-shape. The recess 231 will be described below with reference to FIG. 4. The recess 231 may have a depth hh equal to or smaller than a thickness ht of the high-refractive planarization layer 241. In case that the depth of the recess 231 is equal to the thickness ht of the high-refractive planarization layer 241, the recess 231 may have an opening for exposing the etch stop layer 221. The recess 231 may be filled with a filler having a lower refractive index than that of the high-refractive planarization layer 241.

The refractive index of the high-refractive planarization layer 241 may be in a range of about 1.65 to about 1.75. For example, the first refractive index may be about 1.7. Lights may be refracted or totally reflected due to a difference in refractive index between the recess 231 and the high-refractive planarization layer 241. Accordingly, the light paths of the lights emitted from the emissive layer 172 may be changed into the third direction (e.g., Z-axis direction) or a direction close to the third direction. As a result, the light efficiency of the display device 1 (see FIG. 1) may be improved.

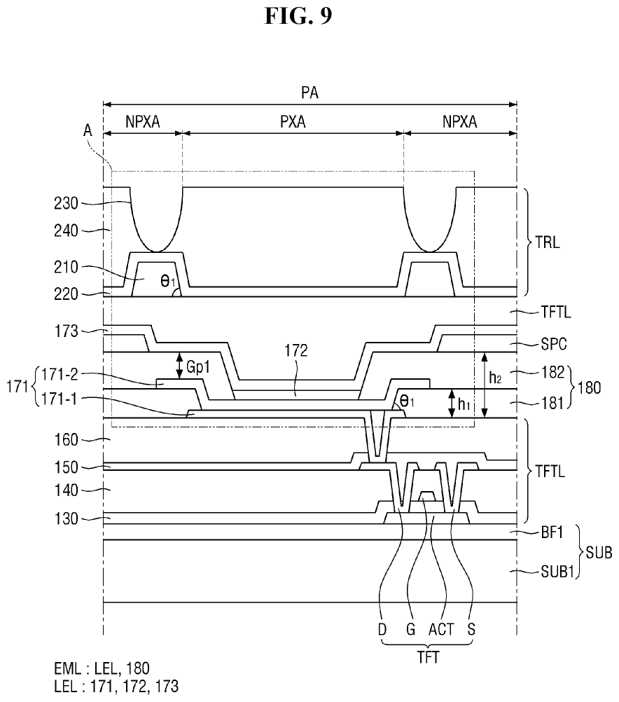

FIG. 9 is a schematic plan view showing a pixel of a display device according to yet an embodiment.

The embodiment of FIG. 9 is substantially identical to the above-described embodiment of FIG. 4 except that pixel electrodes 171-1 and 171-2 and pixel-defining films 181 and 182 are implemented as multiple layers; and, therefore, the redundant descriptions will be omitted for descriptive convenience.

Referring to FIG. 9, the pixel electrode 171 may include a first pixel electrode 171-1 and a second pixel electrode 171-2.

The first pixel electrode 171-1 may be connected to a drain electrode D of a thin-film transistor TFT through a contact hole.

The second pixel electrode 171-2 may be formed on the first pixel electrode 171-1 and a first pixel-defining film 181 to be described below. The second pixel electrode 171-2 may be disposed on an inclined surface of the first pixel-defining film 181 and on the upper surface of the first pixel-defining film 181. The second pixel electrode 171-2 may overlap a low-refractive pattern layer 210 to be described below.

Some lights L among the lights emitted from the emissive layer 172 may not transmit toward the upper side of the second pixel electrode 171-2 but may transmit to the side surface of the second pixel electrode 171-2 toward the first pixel-defining film 181.

The second pixel electrode 171-2 may reflect the lights transmitting toward the side surface of the second pixel electrode 171-2 instead of the upper side of the second pixel electrode 171-2. For example, the second pixel electrode 171-2 may guide the side light from the emissive layer 172 so that the side light may transmit upward without loss. As a result, the light extraction efficiency may be improved, and high emission efficiency may be achieved.

The pixel-defining film 180 may distinguish between light-emitting elements LEL formed on the substrate SUB, and thus may define emission areas. For example, the pixel-defining film 180 may include a first pixel-defining film 181 and a second pixel-defining film 182.

The first pixel-defining film 181 may be formed on the planarization film 160. The first pixel-defining film 181 may not be formed on the entire surface of the planarization film 160, and may include an opening to expose at least a part of the first pixel electrode 171-1. For example, the first pixel-defining film 181 may be formed between adjacent first pixel electrodes 171-1 formed on the planarization film 160.

The first pixel-defining film 181 may be formed to cover the edge portion of the first electrode 171-1.

Each of the first pixel-defining film 181 and the second pixel-defining film 182 may be formed of an organic layer such as an acryl resin, an epoxy resin, a phenolic resin, a polyamide resin and a polyimide resin. The first pixel-defining film 181 and the second pixel-defining film 182 may be made of the same material.

The first pixel-defining film 181 may be formed to have a first inclination angle θ₁₁. The first inclination angle θ₁₁ may be in a range of about 20° to about 70°, and, e.g., in a range of about 30° to about 40°. The inclination angle of the inclined surface of the second pixel electrode 171-2 may be determined by the first inclination angle θ₁₁ of the first pixel-defining film 181. For example, the inclination angle of the inclined surface of the second pixel electrode 171-2 may be equal to the first inclination angle θ₁₁ of the first pixel-defining film 181.

The first pixel-defining film 181 may be formed to have a first height h1 from an upper surface of the planarization film 160. The first height h1 may be in a range of about 1 μm to about 2 μm, but embodiments are not limited thereto.

The second pixel-defining film 182 may be disposed on the first pixel-defining film 181 and the second pixel electrode 171-2. The second pixel-defining film 182 may not be formed on the entire surface of the second pixel electrode 171-2, but may include an opening to expose at least a part of the second pixel electrode 171-2.

The opening formed by the second pixel-defining film 182 may be smaller than the opening formed by the first pixel-defining film 181.

The second pixel-defining film 182 may be formed to have a second height h2 from the upper surface of the planarization film 160. The second height h2 may be in a range of about 1 μm to about 2 μm, but embodiments are not limited thereto.

The edge portion of the second pixel electrode 171-2 may be spaced apart from a common electrode 173 due to the second height h2 of the second pixel-defining film 182. The second pixel-defining film 182 increases the gap Gp1 between the edge portion of the second pixel electrode 171-2 and the common electrode 173, so that the electric field may be prevented from being concentrated at the edge portion of the second pixel electrode 171-2. For example, the second pixel-defining film 182 may prevent a short circuit between the second pixel electrode 171-2 and the common electrode 173.

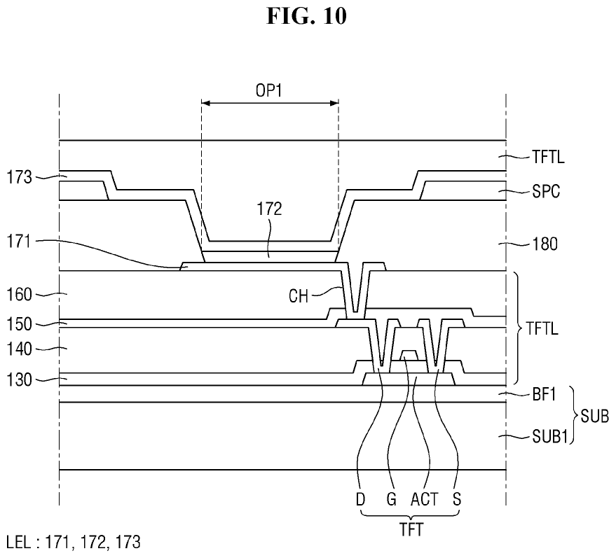

FIGS. 10 to 18 are schematic cross-sectional views showing a part of a display device for illustrating a method of fabricating the display device according to an embodiment.

Referring to FIG. 10, a display panel DP may be prepared by sequentially stacking a thin-film transistor layer TFTL, an emission material layer EML, and a thin-film encapsulation layer TFEL on a substrate SUB. The above elements have been described above with reference to FIGS. 2 to 4; and, therefore, the redundant descriptions will be omitted for descriptive convenience.

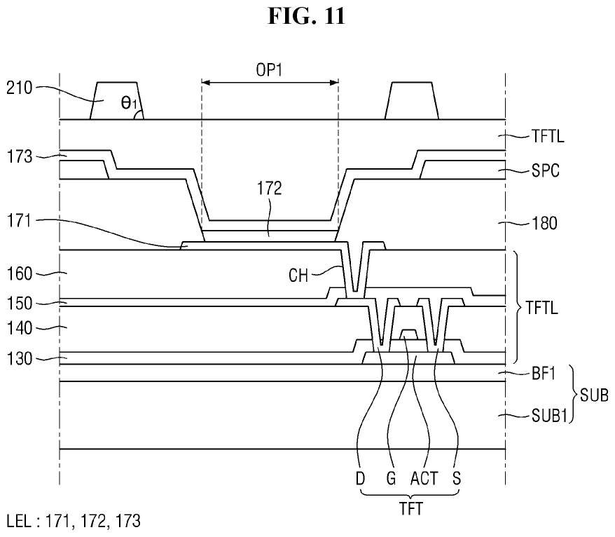

Referring to FIG. 11, the low-refractive pattern layer 210 overlapping a pixel-defining film may be formed on the thin-film encapsulation layer TFEL.

The low-refractive pattern layer 210 may be formed by a photo-lithography process. For example, after a material for forming a low-refractive pattern layer 210 is applied on the thin-film encapsulation layer TFEL, the material for forming the low-refractive pattern layer 210 may be selectively etched by using a mask to form the low-refractive pattern layer 210 so that the low-refractive pattern layer 210 may overlap the pixel-defining film 180. In the photo-lithography process for a mask, the size and position of the low-refractive pattern layer 210 may be readily adjusted, but it is relatively difficult to adjust the thickness of the low-refractive pattern layer 210.

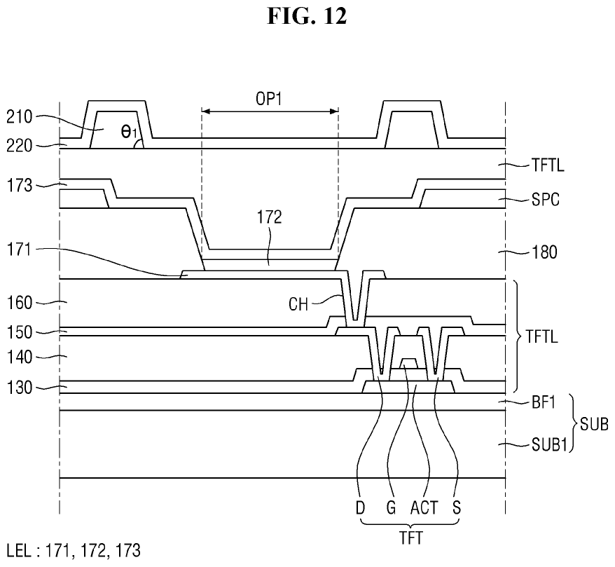

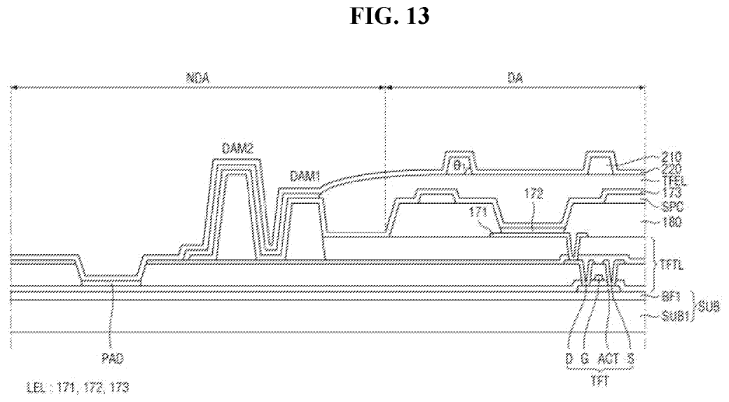

Referring to FIGS. 12 and 13, an etch stop layer 220 may be disposed over the low-refractive pattern layer 210 formed on the thin-film encapsulation layer TFEL. The etch stop layer 220 may be made of an inorganic material such as silicon nitride. The etch stop layer 220 may be disposed not only in the display area DA but also in the non-display area NDA.

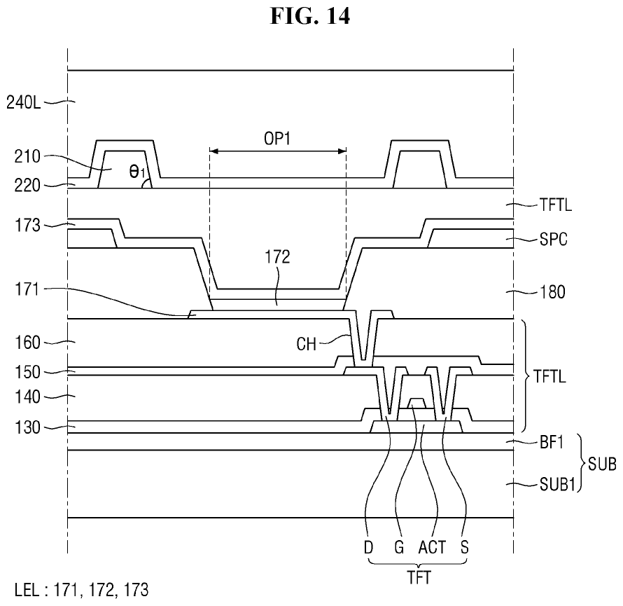

Referring to FIG. 14, a high-refractive planarization material 240L may be applied in a pixel area where the etch stop layer 220 is formed. The high-refractive planarization material 240L may be formed by applying an organic composition INK on the etch stop layer 220 by an inkjet process. In the inkjet process, the thickness of the material may be controlled by adjusting the amount and time of the injection in the injection device. For example, the thickness of the high-refractive planarization layer 240 may be readily adjusted by the inkjet process. The high-refractive planarization material 240L may be a photocurable resin.

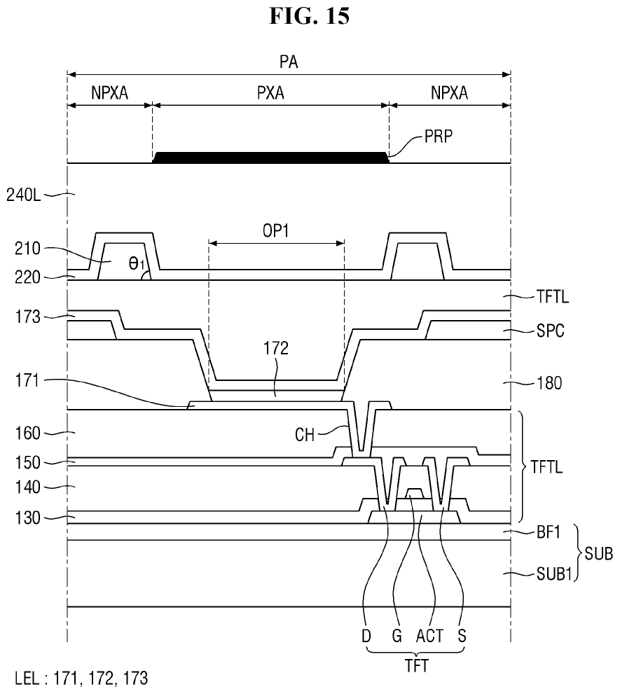

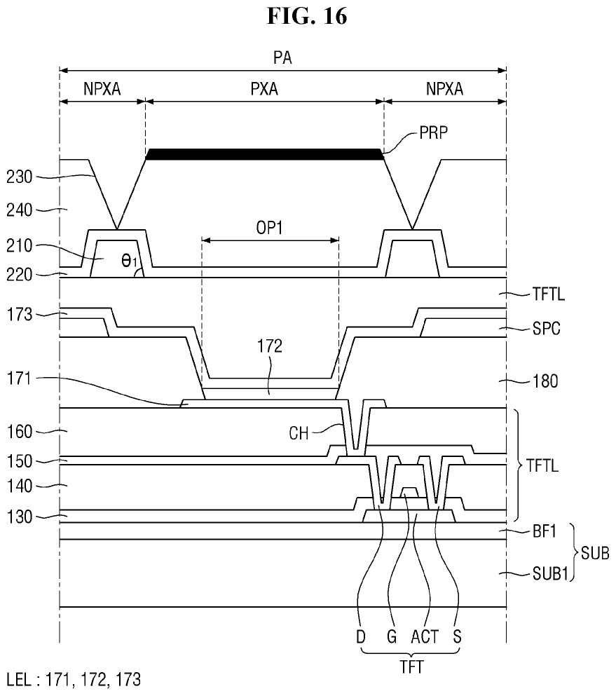

Referring to FIGS. 15 and 16, a recess 230 may be formed in the high-refractive planarization layer 240. Initially, a photoresist pattern layer PRP may be formed on the high-refractive planarization layer 240. The V-shaped recess 230 may be formed by etching the region where the photoresist pattern layer PRP is not formed. In case that the recess 230 is formed, a lift-off process may be performed to remove the photoresist pattern layer PRP.

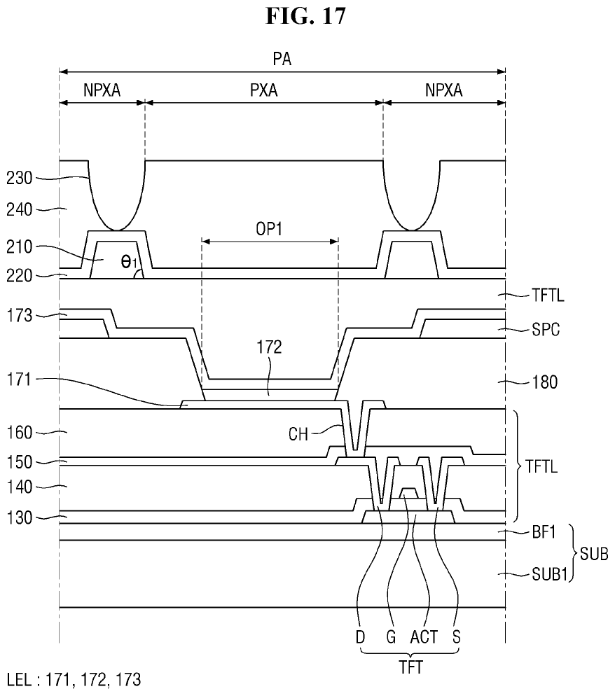

Subsequently, with reference to FIG. 17, the high-refractive planarization layer 240 in which the recess 230 is formed may be cured. For example, the high-refractive planarization layer 240 may be photocured by irradiating the high-refractive planarization layer 240 with ultraviolet (UV) light. Thus, a reflow phenomenon may occur in the V-shaped recess 230, so that the recess 230 may be cured in a U-shape.

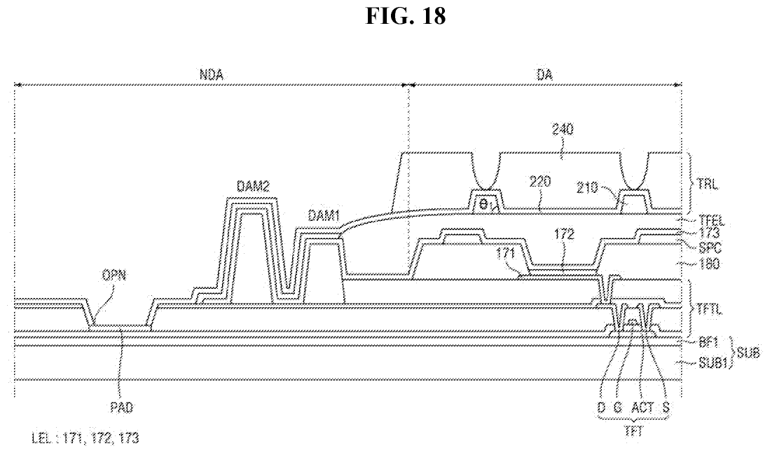

Subsequently, referring to FIG. 18, the etch stop layer 220 disposed on the metal pad PAD in the non-display area NDA may be etched to form the opening OPN, so that the metal pad PAD may be exposed.

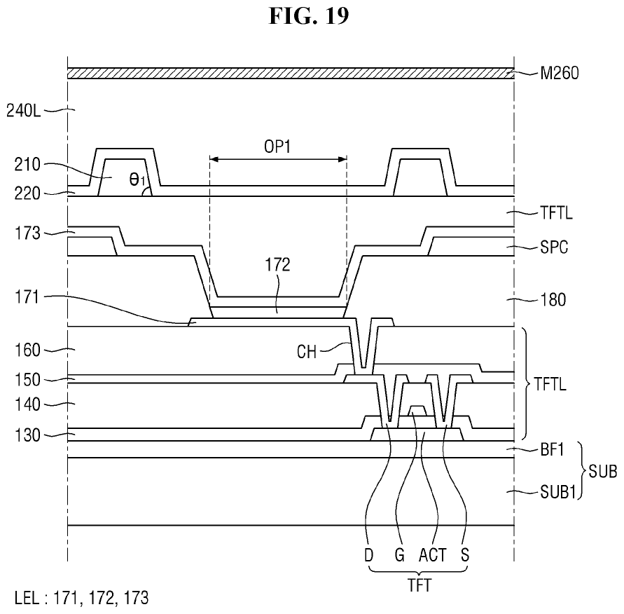

FIGS. 19 to 25 are schematic views for illustrating a method of fabricating a display device according to an embodiment.

As shown in FIGS. 10 to 14, a low-refractive pattern layer 210 and an etch stop layer 220 may be formed on a display panel DP, and a high-refractive planarization material 240L may be applied by an inkjet process.

Subsequently, as shown in FIG. 19, a hard mask M260 may be placed on the high-refractive planarization material 240L. The hard mask M260 may be formed as a metal film.

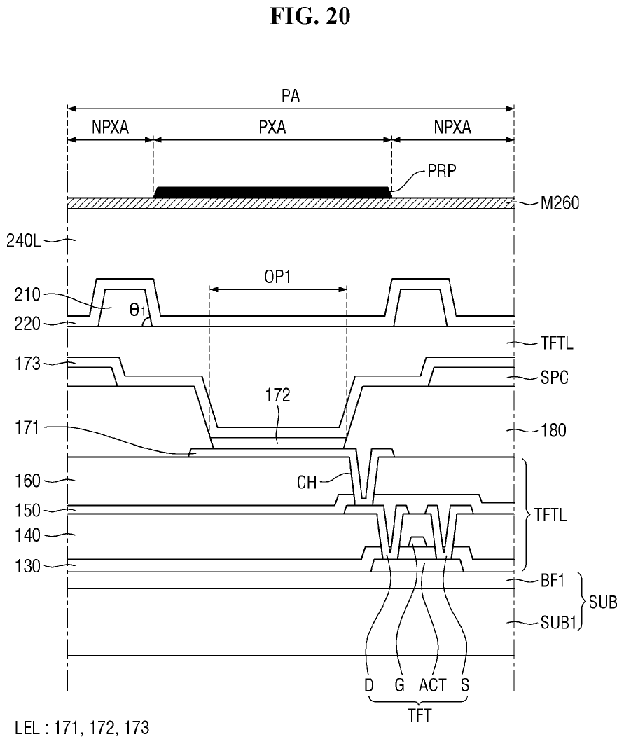

Subsequently, the photoresist pattern layer PRP may be patterned on the hard mask M260 as shown in FIG. 20. The photoresist pattern layer PRP may be patterned by a dry etching process. However, embodiments are not limited thereto.

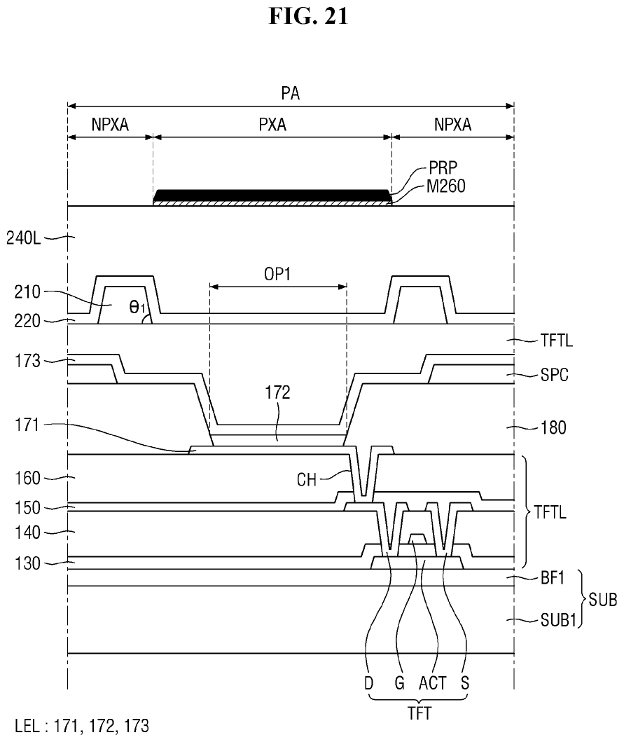

Subsequently, as shown in FIG. 21, the hard mask M260 under the photoresist pattern layer PRP may be patterned by using the photoresist pattern layer PRP as a mask. The hard mask M260 may be patterned by a dry etching process. However, embodiments are not limited thereto.

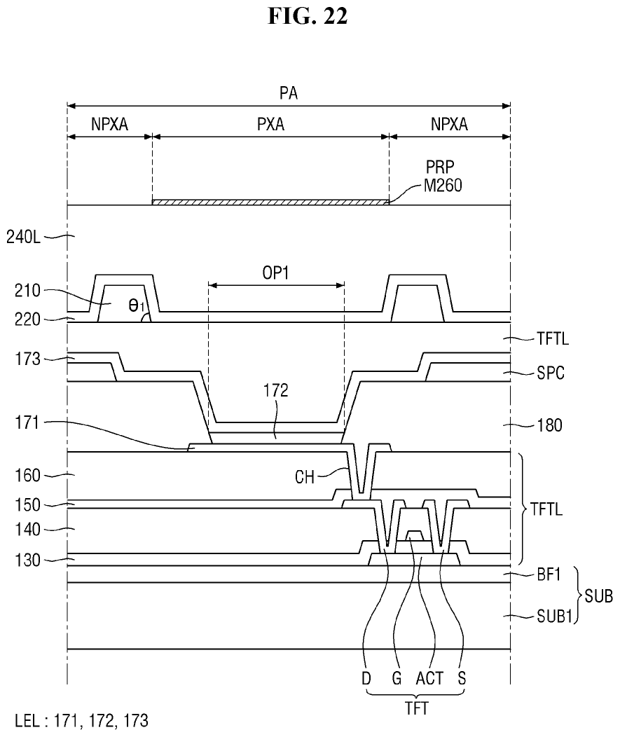

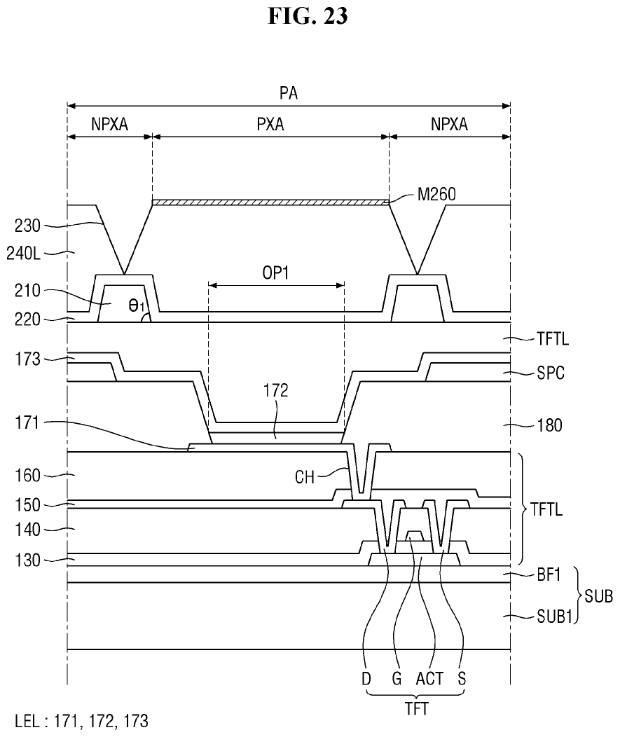

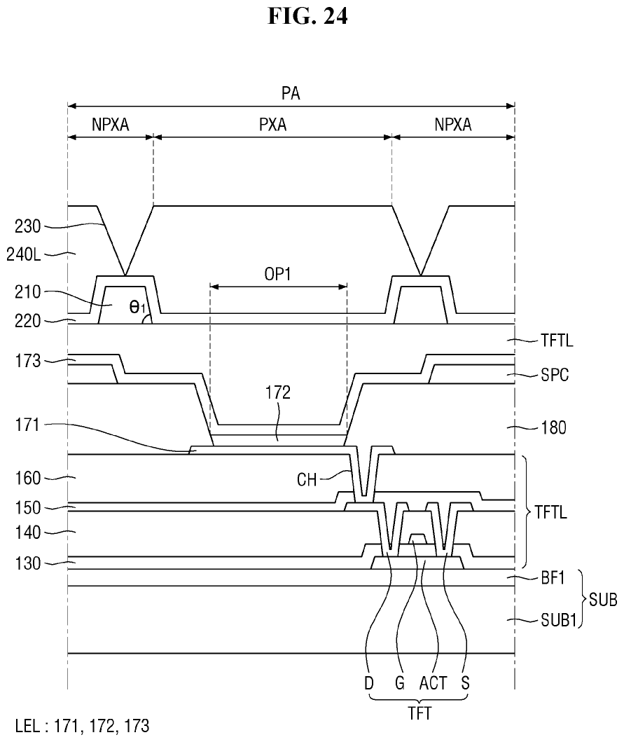

Subsequently, the photoresist pattern layer PRP may be removed by a lift-off process as shown in FIG. 22, and a recess 230 may be etched in a V-shape by using the patterned hard mask M260 as shown in FIG. 23. Subsequently, the patterned hard mask M260 may be removed as shown in FIG. 24.

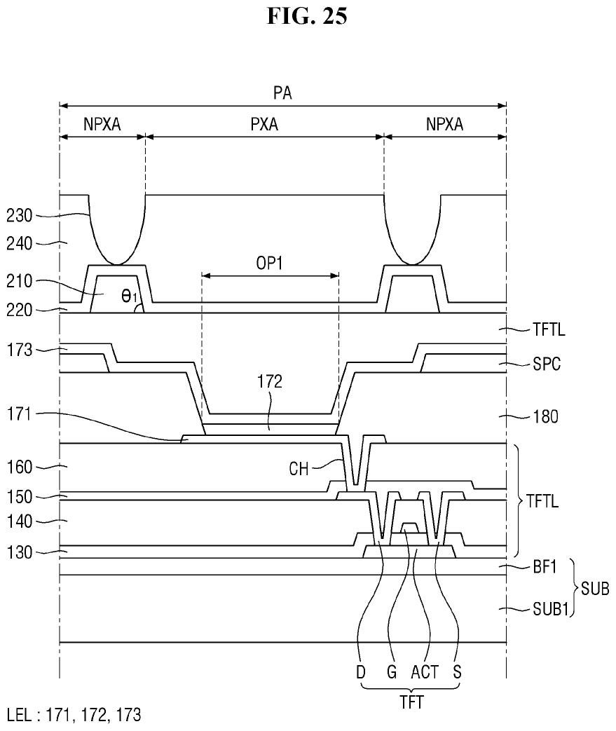

Subsequently, with reference to FIG. 25, the high-refractive planarization layer 240 in which the recess 230 is formed may be cured. For example, the high-refractive planarization layer 240 may be photocured by irradiating the high-refractive planarization layer 240 with UV light. Thus, a reflow phenomenon may occur in the V-shaped recess 230, so that the recess 230 may be cured in a U-shape.

Subsequently, referring to FIG. 18, the etch stop layer 220 disposed on the metal pad PAD in the non-display area NDA may be etched to form the opening OPN, so that the metal pad PAD may be exposed.

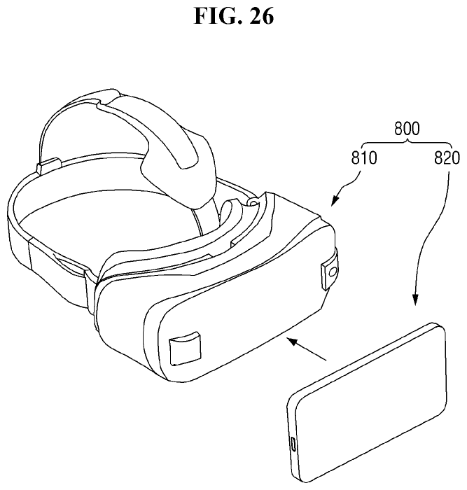

FIG. 26 is a schematic view showing a configuration of a head-mounted display device according to an embodiment.

Referring to FIG. 26, a head-mounted display device 800 according to an embodiment may include a head-mounted device 810 and a display device 820.

The head-mounted device 810 may be coupled with the display device 820. The display device 820 may include a display panel that displays images. The display device 820 may include the display device having the total reflection layer TRL described herein.

The head-mounted device 810 may include a connector for electrical connection to the display device 820 and a frame for physical connection. For example, the head-mounted device 810 may include a cover for preventing an external shock and preventing the display device 820 from being detached.

For example, the head-mounted device 810 may be coupled with the display device 820, and the display device 820 may include the high-refractive planarization layer having a groove overlapping a pixel-defining film, thereby guiding side lights to transmit upward. Accordingly, the display device 820 may improve visibility.

In concluding the detailed description, those skilled in the art will appreciate that many variations and modifications may be made to the embodiments without substantially departing from the principles of the invention. Therefore, the disclosed embodiments of the invention are used in a generic and descriptive sense only and not for purposes of limitation.

What is claimed is:

1. A display device comprising:
a substrate;
an emission material layer disposed on the substrate, the emission material layer comprising:
a pixel including a pixel electrode, an emissive layer, and a common electrode; and
a pixel-defining film defining the pixel;
a thin-film encapsulation layer disposed on the emission material layer;
a low-refractive pattern layer overlapping the pixel-defining film and disposed on the thin-film encapsulation layer;
an etch stop layer disposed on the low-refractive pattern layer, the etch stop layer formed of an inorganic material; and
a high-refractive planarization layer formed on the etch stop layer,
wherein the high-refractive planarization layer includes a recess overlapping the low-refractive pattern layer.

2. The display device of claim 1, wherein
the recess of the high-refractive planarization layer is aligned with the low-refractive pattern layer, and
a width of the recess gradually decreases as being closer to the low-refractive pattern layer from an upper surface of the high-refractive planarization layer.

3. The display device of claim 2, wherein the recess has a depth greater than a thickness of the low-refractive pattern layer.

4. The display device of claim 2, wherein the recess includes an opening exposing the etch stop layer.

5. The display device of claim 1, wherein the recess surrounds the emissive layer in a plan view.

6. The display device of claim 1, wherein the low-refractive pattern layer surrounds the emissive layer in a plan view.

7. The display device of claim 1, wherein the high-refractive planarization layer has a refractive index greater than a refractive index of the low-refractive pattern layer by about 0.05 to about 0.3.

8. The display device of claim 7, wherein the etch stop layer has a refractive index that is smaller than the refractive index of the high-refractive planarization layer and greater than the refractive index of the low-refractive pattern layer.

9. The display device of claim 1, wherein
the substrate comprises a display area overlapping the emissive layer and a non-display area around the display area, and
the etch stop layer entirely covers the display area and the non-display area.

10. The display device of claim 9, wherein
the substrate further comprises a metal pad disposed in the non-display area, and
the etch stop layer comprises an opening exposing the metal pad.

11. A display device comprising:
a substrate;
an emission material layer disposed on the substrate, the emission material layer comprising:
a pixel having a pixel electrode, an emissive layer and a common electrode; and
a pixel-defining film defining the pixel;
a thin-film encapsulation layer disposed on the emission material layer;
an etch stop layer disposed on the thin-film encapsulation layer, the etch stop layer formed of an inorganic material; and
a high-refractive planarization layer formed on the etch stop layer,
wherein the high-refractive planarization layer includes a recess overlapping the pixel-defining film.

12. The display device of claim 11, wherein
the recess of the high-refractive planarization layer extends along the the pixel-defining film, and
a width of the recess gradually decreases as being closer the etch stop layer from an upper surface of the high-refractive planarization layer.

13. The display device of claim 12, wherein the recess has an opening exposing the etch stop layer.

14. The display device of claim 11, wherein the recess surrounds the emissive layer in a plan view.

15. The display device of claim 11, wherein the high-refractive planarization layer has a refractive index greater than a refractive index of the etch stop layer.

16. The display device of claim 11, wherein the recess is filled with a filler having a refractive index smaller than the refractive index of the high-refractive planarization layer.

17. The display device of claim 11, wherein
the substrate comprises a display area overlapping the emissive layer and a non-display area around the display area, and
the etch stop layer entirely covers the display area and the non-display area.

18. The display device of claim 17, wherein
the substrate further comprises a metal pad disposed in the non-display area, and
the etch stop layer comprises an opening exposing the metal pad.

19. A method of fabricating a display device, the method comprising:
forming a display panel by sequentially stacking a substrate, an emission material layer comprising a pixel-defining film and a pixel, and a thin-film encapsulation layer for protecting the emission material layer;
forming a low-refractive pattern layer on the thin-film encapsulation layer overlapping the pixel-defining film;
forming an etch stop layer entirely on the display panel to cover the low-refractive pattern layer;
forming a high-refractive planarization material on the etch stop layer;
etching the high-refractive planarization material to form a recess overlapping the low-refractive pattern layer; and
forming a high-refractive planarization layer by curing the high-refractive planarization material.

20. The method of claim 19, wherein
the low-refractive pattern layer extends along the pixel-defining film,
the recess of the high-refractive planarization layer is aligned with the low-refractive pattern layer, and
the forming of the etch stop layer comprises: forming the etch stop layer entirely in a display area and a non-display area of the display panel.

21. The method of claim 20, further comprising:
forming an opening exposing a metal pad disposed in the non-display area by etching the etch stop layer.

22. The method of claim 20, wherein
the forming of the low-refractive pattern layer is performed by a photo-lithography process, and
the forming of the high-refractive planarization material on the etch stop layer is performed by an ink-jet process.

23. The method of claim 20, wherein the recess is formed by etching by using a hard mask.
